(19) United States
(12) Patent Application Publication
(10) Pub. No.: US 2015/0171245 A1
(43) Pub. Date: Jun. 18, 2015

(54) Flip-chip Solar Cell Chip and Fabrication Method Thereof

(71) Applicant: XIAMEN SANAN OPTOELECTRONICS TECHNOLOGY CO., LTD., Xiamen (CN)

(72) Inventors: WEIPING XIONG, Xiamen (CN); GUIJIANG LIN, Xiamen (CN); ZHIMIN WU, Xiamen (CN); MINGHUI SONG, Xiamen (CN); HUI AN, Xiamen (CN)

(73) Assignee: XIAMEN SANAN OPTOELECTRONICS TECHNOLOGY CO., LTD., Xiamen (CN)

(21) Appl. No.: 14/633,947

(22) Filed: Feb. 27, 2015

Related U.S. Application Data
(63) Continuation of application No. PCT/CN2013/082786, filed on Sep. 2, 2013.

(30) Foreign Application Priority Data
Sep. 4, 2012 (CN) 201210322001.9

(51) Int. Cl. H01L 31/0352; H01L 31/0224; H01L 31/18

(52) U.S. Cl. CPC H01L 31/035281; H01L 31/1876; H01L 31/1892; H01L 31/022433

(57) ABSTRACT

A flip-chip solar cell chip includes a bonding transfer substrate; a metal bonding layer; a flip-chip solar cell epitaxial layer that bonds with the bonding transfer substrate with the metal bonding layer; the flip-chip solar cell epitaxial layer and the metal bonding layer are divided into two or more portions; the surface of the flip-chip solar cell epitaxial layer has a front electrode; and the metal bonding layer is connected with the ends of the front electrode to form a series connection of the divided epitaxial layer. Advantageously, the division of the solar cell epitaxial layer into a plurality of completely-separated portions greatly reduces photo currents and power loss of cell chip series resistance while realizing multiplied increase of output voltage, thereby improving photoelectric conversion efficiency. The use of metal bonding layer as the back electrode realizes extremely low resistance loss of the back electrode.

### CROSS-REFERENCE TO RELATED APPLICATIONS

The present application is a continuation of, and claims priority to, PCT/CN2013/082786 filed on Sep. 2, 2013, which claims priority to Chinese Patent Application No. 201210322001.9 filed on Sep. 4, 2012. The disclosures of these applications are hereby incorporated by reference in their entirety.

### BACKGROUND

Solar cell power generation plays an important role in future new energy field. However, its existing development is restricted by high power generation cost. To solve this problem, the most direct and important method is to improve its photoelectric conversion efficiency. Among the many factors that influence the photoelectric conversion efficiency of solar cell, the power loss of internal series resistance is the most important one.

The power loss of cell series resistance is determined by the series resistance and photo current, i.e., the power loss is in direct proportion to the square of the photo current when the series resistance is constant. Therefore, it is an effective method to reduce the power loss of cell series resistance by reducing the photo current while increasing the cell voltage, which is particularly important in the application of high-concentration solar cell (So far, most concentrator solar cells are applied in about 1000× concentrating conditions and the current density is up to 13-15 A/cm²).

Reduction of cell chip area is an effective way to reduce photo current and to reduce the series resistance at the same time. However, this method will lead to multiplied increase of packing amount (also the packaging cost) of cell when the generating capacity is same. For example, a 1 cm² high-concentration solar cell chip only requires one solar receiver. However, such chip requires 25 solar receivers if it is cut into multiple 0.04 cm² chips. In consideration of high packaging cost, the power generation cost may be increased even though the cell efficiency is improved.

### SUMMARY

To solve the above problem, the present invention discloses a flip-chip solar cell chip and fabrication method thereof.

According to a first aspect of the present disclosure, a flip-chip solar cell chip is provided, comprising an insulating transfer substrate, a metal bonding layer and a flip-chip solar cell epitaxial layer, wherein: the flip-chip solar cell epitaxial layer bonds with the transfer substrate with the metal bonding layer; the flip-chip solar cell epitaxial layer and the metal bonding layer are cut into a plurality of units; the surface of the flip-chip solar cell epitaxial layer cut into a plurality of units has a front electrode; and the metal bonding layer is connected with the ends of the front electrode to form series connection of the cut units of the epitaxial layer.

Preferably, the transfer substrate is polished glass, undoped silicon wafer or organic insulating substrate.

Preferably, the metal bonding layer is high-conductive material, serving as a bonding medium layer and a back electrode.

Preferably, one end of the exposed metal bonding layer of each unit is connected with the epitaxial layer of the unit and the other end extends to the epitaxial layer of adjacent unit. Further, between two adjacent units, the metal bonding layer of a first unit connects with the front electrode of a second unit via a metal connecting layer. Further, an insulating layer is provided between two adjacent units; the metal connecting layer is over the insulating layer; the insulating film is wider while shorter than the metal connecting layer, which guarantees the electric insulation between the metal connecting layer and the side wall of the epitaxial layer, so as to form a plurality of small and completely-separated solar cells over the same transfer substrate.

According to a second aspect of the present disclosure, a fabrication method of flip-chip solar cell chip is disclosed, comprising: 1) providing an insulating transfer substrate and a flip-chip solar cell epitaxial layer; 2) transferring the flip-chip solar cell epitaxial layer to the insulating transfer substrate through the metal bonding layer via metal bonding process; 3) cutting the flip-chip solar cell epitaxial layer and the metal bonding layer into a plurality of units; 4) etching the solar cell epitaxial layer of each unit and exposing portion of the metal bonding layer; 5) preparing a front electrode over the epitaxial layer front surface of each unit; and 6) connecting the exposed metal bonding layer with the ends of front electrode to form series connection.

In this method, preferably, in step 4), one end of the exposed metal bonding layer of each unit is connected with the solar cell epitaxial layer and the other end extends to the epitaxial layer of adjacent unit. Step 6) comprises: forming an insulating layer between the exposed metal bonding layer of each unit and the epitaxial layer of adjacent unit; forming a metal connecting layer over the insulating layer, which connects the exposed metal bonding layer and the front electrode of adjacent unit; wherein, the insulating film is wider while shorter than the metal connecting layer, which guarantees the electric insulation between the metal connecting layer and the side wall of the epitaxial layer, so as to form a plurality of small and completely-separated solar cells over the same transfer substrate.

The present disclosure has the advantage that the division of the solar cell epitaxial layer into a plurality of completely-separated portions will greatly reduce the photo current and the power loss of cell chip series resistance while realizing multiplied increase of output voltage, thereby improving photoelectric conversion efficiency of the cell chip and controlling packaging cost since the separated portions are not completely separated. Further, use of metal bonding layer as the back electrode realizes extremely low resistance loss of back electrode for it avoids epitaxial growth of the high-doped and thick semi-conductor photo current collection layer at the back in the absence of flip-chip bonding, which has high resistance and resistance power loss.

### BRIEF DESCRIPTION OF THE DRAWINGS

FIG. 1 is schematic diagram of a first step in a fabrication flow of a flip-chip solar cell chip according to some implementations;

FIG. 2 is schematic diagram of a second step in a fabrication flow of a flip-chip solar cell chip according to some implementations;

FIG. 3 is schematic diagram of a third step in a fabrication flow of a flip-chip solar cell chip according to some implementations;

FIG. 4 is schematic diagram of a fourth step in a fabrication flow of a flip-chip solar cell chip according to some implementations;

FIG. 5 is schematic diagram of a fifth step in a fabrication flow of a flip-chip solar cell chip according to some implementations;

FIG. 6 is schematic diagram of a sixth step in a fabrication flow of a flip-chip solar cell chip according to some implementations;

FIG. 7 is schematic diagram of a seventh step in a fabrication flow of a flip-chip solar cell chip according to some implementations;

FIG. 8 is schematic diagram of an eighth step in a fabrication flow of a flip-chip solar cell chip according to some implementations;

FIG. 9 is schematic diagram of a ninth step in a fabrication flow of a flip-chip solar cell chip according to some implementations;

FIG. 10 is schematic diagram of a tenth step in a fabrication flow of a flip-chip solar cell chip according to some implementations;

FIG. 11 is schematic diagram of en eleventh step in a fabrication flow of a flip-chip solar cell chip according to some implementations;

FIG. 12 is schematic diagram of a twelfth step in a fabrication flow of a flip-chip solar cell chip according to some implementations.

In the drawings:
001: transfer substrate;
002: flip-chip solar cell epitaxial layer;
003: flip-chip solar cell epitaxial substrate;
004: metal bonding layer;
005: insulating layer;
006: metal connecting layer;
007: front electrode.

### DETAILED DESCRIPTION

The following embodiments disclose a flip-chip solar cell chip structure and fabrication method thereof. The device structure comprises an insulating transfer substrate, a metal bonding layer and a flip-chip solar cell epitaxial layer, wherein, the flip-chip solar cell epitaxial layer connects with the transfer substrate via the metal bonding layer. The flip-chip solar cell epitaxial layer and the metal bonding layer are cut into a plurality of units; the surface of epitaxial layer of each unit has a front electrode connected with the ends of the metal bonding layer to form series connection of the cut units of the epitaxial layer. In some embodiments, the insulating transfer substrate can be such insulation materials as polished glass, silicon wafer or organic insulating substrate. The heat-dissipation substrate is mostly preferred.

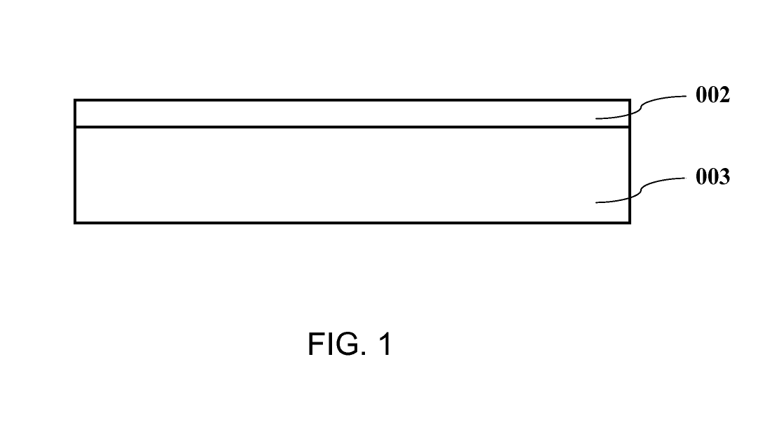

Detailed description will be given to the realization of the present disclosure, which is not restrictive of the protection scope of the invention. A fabrication method of flip-chip solar cell chip mainly comprises substrate transferring, epitaxial wafer dividing and conducting connection. Detailed description will be given in combination with FIGS. 1-12.

As shown in FIG. 1, provide a flip-chip solar cell epitaxial wafer and an insulating transfer substrate 001. The flip-chip solar cell epitaxial wafer comprises a flip-chip solar cell epitaxial substrate 003 and an epitaxial layer 002, and the bonding transfer substrate 001 is an undoped silicon wafer.

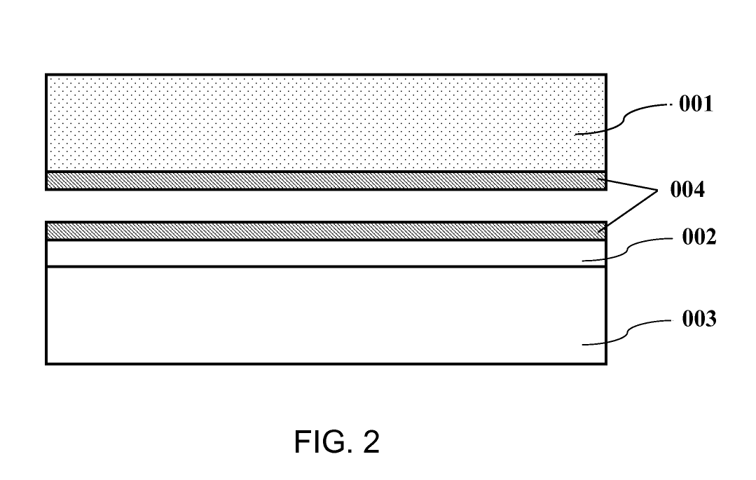

As shown in FIG. 2, evaporate a metal bonding layer 004 over the surfaces of the flip-chip solar cell epitaxial layer 002 and the transfer substrate 001 respectively by electron beam evaporation.

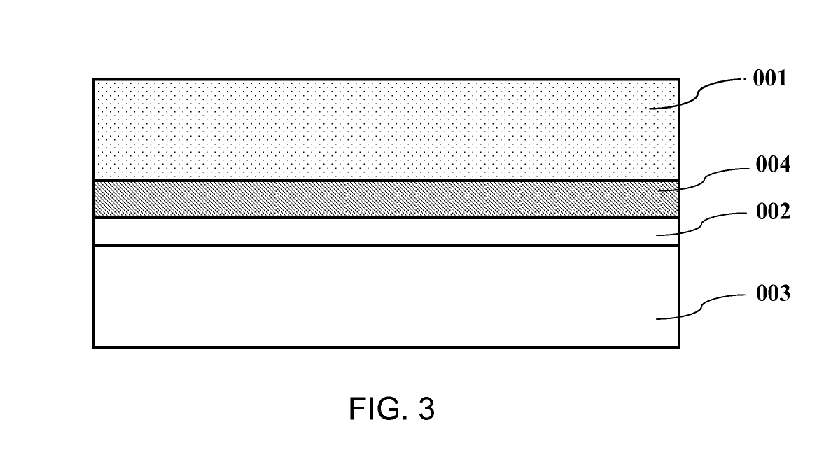

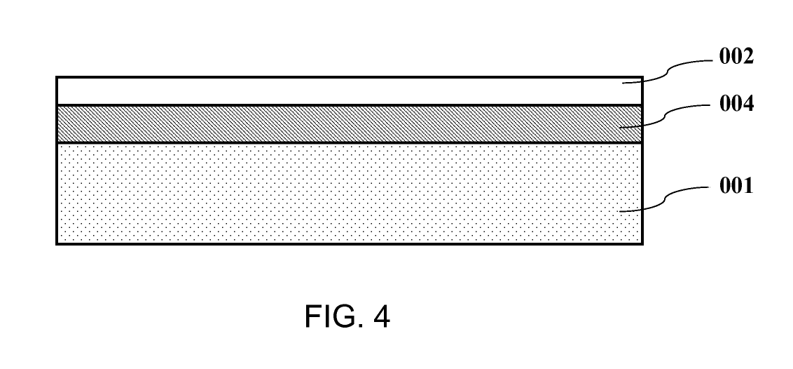

As shown in FIG. 3, bond the flip-chip solar cell epitaxial wafer and the bonding transfer substrate with the metal bonding layer 004 via metal bonding process. As shown in FIG. 4, remove the flip-chip solar cell epitaxial substrate 003 via chemical corrosion.

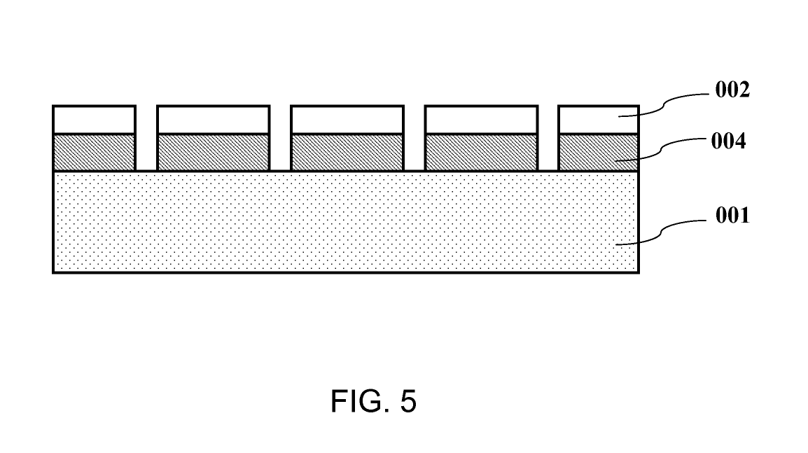

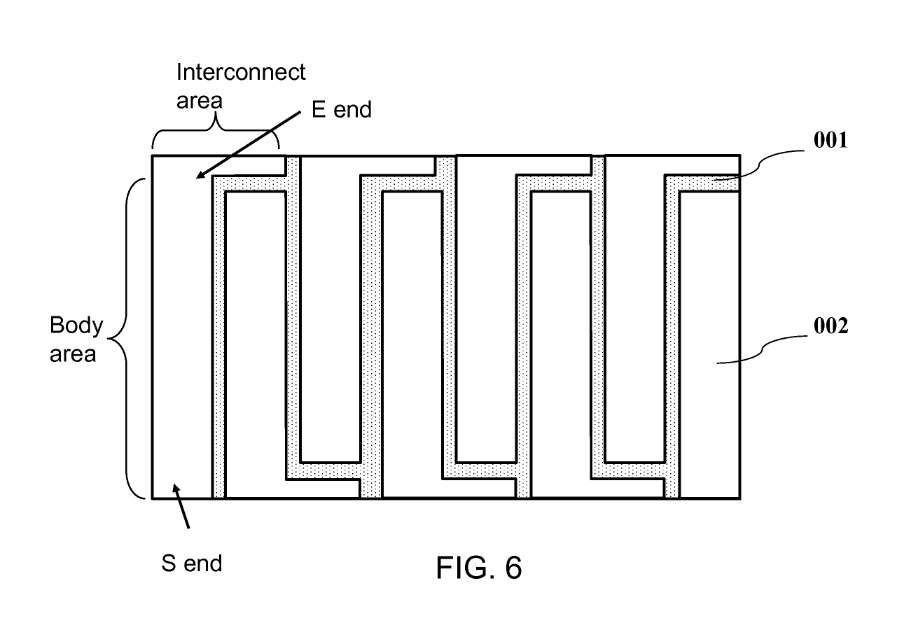

As shown in FIG. 5, etch the flip-chip solar cell epitaxial layer 002 and the metal bonding layer 004 into a plurality of units via photoetching and etching process, wherein, the space between adjacent patterns is 20-50 μm to eliminate area waste while ensuring complete division of patterns. FIG. 6 is the top view of a completed sample. As shown in the figure, each unit appears “L-shaped” distribution and is divided into a body area and an interconnect area, wherein, the end-protruded portion is the interconnect area, and the starting side S of each unit is at the body area and the ending side E is at the interconnect area.

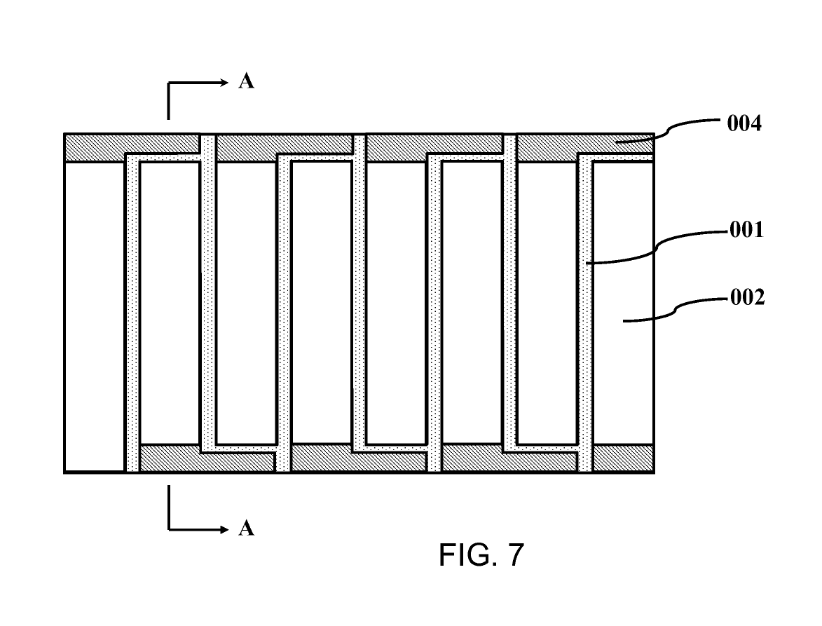

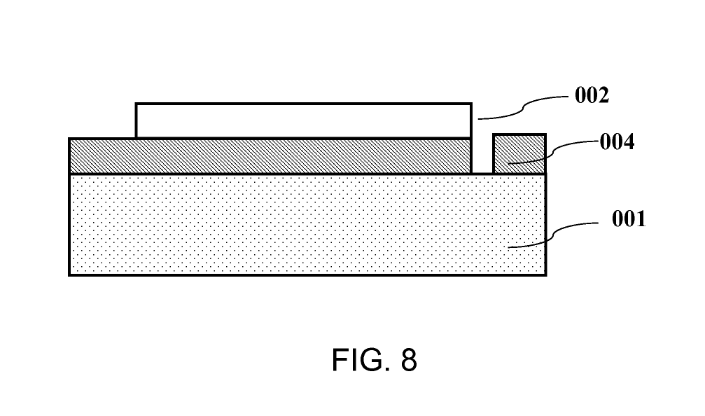

As shown in FIG. 7, etch and remove the epitaxial layer at interconnect area of each unit via photoetching and etching process to expose portion of metal bonding layer 004 under the epitaxial layer. FIG. 8 is a cross section along Line A-A.

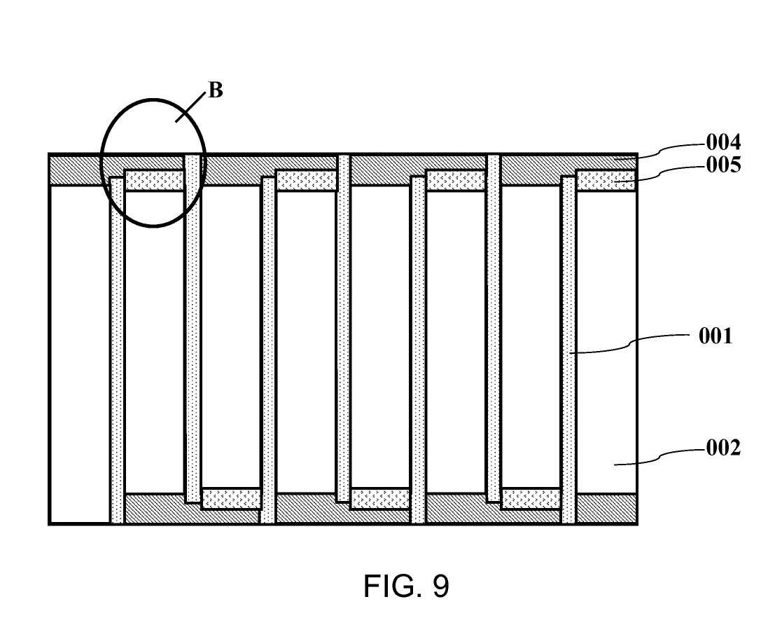

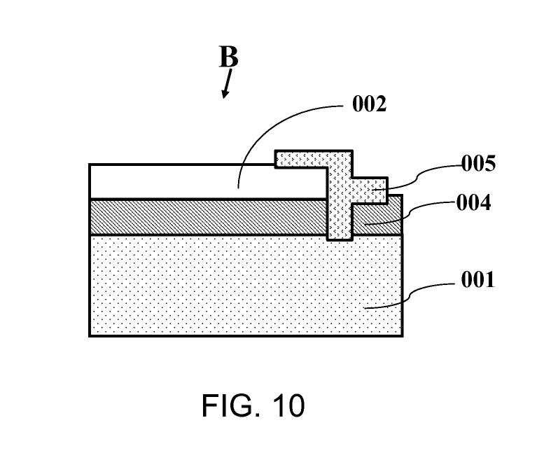

As shown in FIG. 9, evaporate an insulating layer over the cell chip and form an insulating layer 005 crossing edges of adjacent divided units via photoetching and etching process. The insulating film is electrode beam evaporated silicon dioxide. FIG. 10 is a part section view of Portion B in FIG. 9.

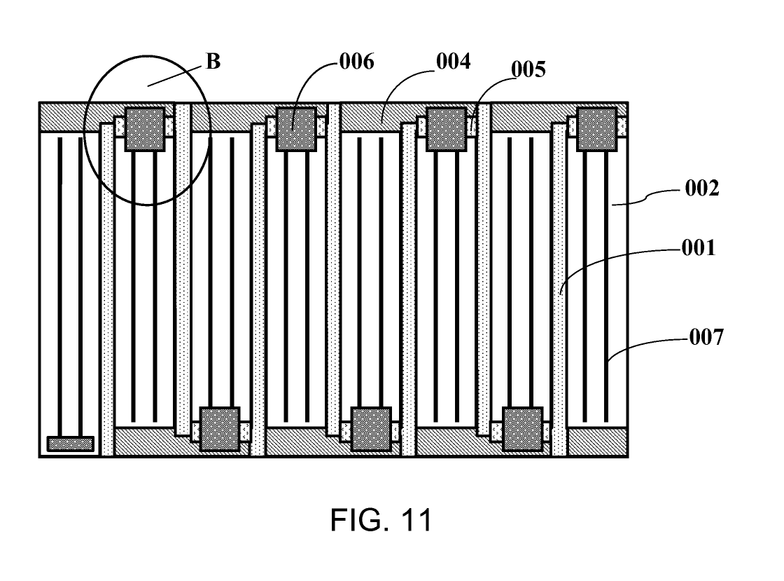

As shown in FIG. 11, form a metal connecting layer 006 over the insulating layer 005 via photoetching, metal evaporation and metal flipping-off and form a front electrode 007 over the divided epitaxial layer surface. The insulating film 005 is a bit wider while shorter than the metal connecting layer 006 to realize electric connection between the back electrode (i.e., the metal bonding layer 004) of the adjacent cut unit and the front electrode 007, while avoiding electric leakage and even short circuit from the epitaxial layer side wall.

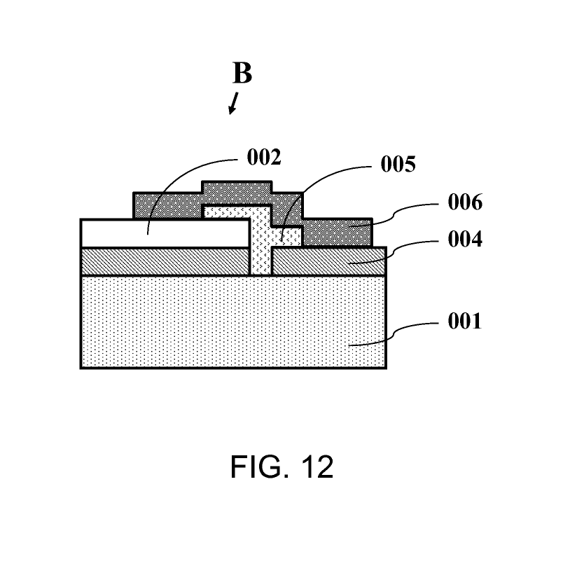

FIG. 12 is a part section view of Portion B in FIG. 11. As shown in the figure, at the place under end connection portion of two adjacent divided units is covered with an insulating layer 005, which avoids electric leakage and short circuit from the epitaxial layer side wall. A metal connecting line 006 is formed over the insulating layer 005 to realize connection between the metal bonding layer and the front electrode so as to form a small series solar cell array over the same transfer substrate.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A flip-chip solar cell chip, comprising:
an insulating transfer substrate;
a metal bonding layer; and
a flip-chip solar cell epitaxial layer,
wherein:
the flip-chip solar cell epitaxial layer bonds with the transfer substrate with the metal bonding layer;
the flip-chip solar cell epitaxial layer and the metal bonding layer are divided into a plurality of units, each unit having an “L” shape and comprising a body area and an interconnect area, wherein the interconnect area comprises an end protrusion portion, wherein a starting side of each unit is at the body area and an ending side is at the interconnect area;
a surface of the divided flip-chip solar cell epitaxial layer has a front electrode; and
the metal bonding layer is coupled with ends of the front electrode to form a series connection of the divided flip-chip solar cell epitaxial layer.

2. The solar cell chip of claim 1, wherein the transfer substrate comprises at least one of a polished glass, an undoped silicon wafer, or an organic insulating substrate.

3. The solar cell chip of claim 1, wherein the metal bonding layer comprises a highly-conductive material, serving as a bonding medium layer and a back electrode.

4. The solar cell chip of claim 3, wherein one end of an exposed metal bonding layer of each unit is connected with the epitaxial layer of the unit and another end extends to the epitaxial layer of adjacent units.

5. The solar cell chip of claim 4, wherein between two adjacent units, the metal bonding layer of a first unit connects with the epitaxial layer of a second unit via a metal connecting layer.

6. The solar cell chip of claim 5, wherein an insulating layer is provided between two adjacent units; the metal connecting layer is disposed over the insulating layer.

7. The solar cell chip of claim 6, wherein the insulating film is wider in width and shorter in length compared with the metal connecting layer, thereby guaranteeing an electric insulation between the metal connecting layer and a side wall of the epitaxial layer, so as to form a plurality of small and completely-separated solar cells over the same transfer substrate.

8. A fabrication method of a flip-chip solar cell chip, comprising:
1) providing an insulating transfer substrate and a flip-chip solar cell epitaxial layer;
2) transferring the flip-chip solar cell epitaxial layer to the insulating transfer substrate through a metal bonding layer via a metal bonding process;
3) dividing the flip-chip solar cell epitaxial layer and the metal bonding layer into a plurality of units; each unit having an “L” shape and comprising a body area and an interconnect area, wherein the interconnect area comprises an end protrusion portion, a starting side of each unit is at the body area and an ending side is at the interconnect area;
4) etching the solar cell epitaxial layer at the interconnect area of each unit and exposing a portion of the metal bonding layer;
5) preparing a front electrode over a front surface of the epitaxial layer of each unit; and
6) connecting the exposed portion of metal bonding layer with ends of the front electrode to form a series connection.

9. The fabrication method of claim 8, wherein in step 4), one end of the exposed portion of the metal bonding layer of each unit is connected with the solar cell epitaxial layer and another end extends to the epitaxial layer of adjacent units.

10. The fabrication method of claim 8, wherein Step 6) comprises:
forming an insulating layer between the exposed metal bonding layer of each unit and the epitaxial layer of an adjacent unit;
forming a metal connecting layer over the insulating layer, which connects the exposed metal bonding layer and a front electrode of adjacent unit;
wherein the insulating film is wider in width and shorter in length compared with the metal connecting layer, thereby guaranteeing an electric insulation between the metal connecting layer and the side wall of the epitaxial layer, so as to form a plurality of small and completely-separated solar cells over the same transfer substrate.

11. A solar power system comprising a plurality of flip-chip solar cell chips, each chip comprising:
an insulating transfer substrate;
a metal bonding layer; and
a flip-chip solar cell epitaxial layer,
wherein:
the flip-chip solar cell epitaxial layer bonds with the transfer substrate with the metal bonding layer;
the flip-chip solar cell epitaxial layer and the metal bonding layer are divided into a plurality of units, each unit having an “L” shape and comprising a body area and an interconnect area, wherein the interconnect area comprises an end protrusion portion, wherein a starting side of each unit is at the body area and an ending side is at the interconnect area;
a surface of the divided flip-chip solar cell epitaxial layer has a front electrode; and
the metal bonding layer is coupled with ends of the front electrode to form a series connection of the divided flip-chip solar cell epitaxial layer.

12. The solar power system of claim 11, wherein the transfer substrate comprises at least one of a polished glass, an undoped silicon wafer, or an organic insulating substrate.

13. The solar power system of claim 11, wherein the metal bonding layer comprises a highly-conductive material, serving as a bonding medium layer and a back electrode.

14. The solar power system of claim 13, wherein one end of an exposed metal bonding layer of each unit is connected with the epitaxial layer of the unit and another end extends to the epitaxial layer of adjacent units.

15. The solar power system of claim 14, wherein between two adjacent units, the metal bonding layer of a first unit connects with the epitaxial layer of a second unit via a metal connecting layer.

16. The solar power system of claim 15, wherein an insulating layer is provided between two adjacent units; the metal connecting layer is disposed over the insulating layer.

17. The solar power system of claim 16, wherein the insulating film is wider in width and shorter in length compared with the metal connecting layer, thereby guaranteeing an electric insulation between the metal connecting layer and a side wall of the epitaxial layer, so as to form a plurality of small and completely-separated solar cells over the same transfer substrate.
